(19) United States
(12) Patent Application Publication
(10) Pub. No.: US 2012/0068740 A1
(43) Pub. Date: Mar. 22, 2012

(54) VOLTAGE OUTPUT CIRCUT

(75) Inventors: Taku SOGABE, Kanagawa-ken (JP); Akira KUMAMOTO, Tokyo (JP)

(73) Assignee: KABUSHIKI KAISHA TOSHIBA, Tokyo (JP)

(21) Appl. No.: 13/051,187

(22) Filed: Mar. 18, 2011

(30) Foreign Application Priority Data
Sep. 17, 2010 (JP) 2010-209179

(51) Int. Cl. H03K 3/00

(52) U.S. Cl. 327/110; 327/108

(57) ABSTRACT

According to one embodiment, a voltage output circuit is disclosed. The circuit has: a transistor connected between a first terminal and a second terminal, the transistor having a gate connected to a first node and being switched in accordance with control signal; a first pull-up circuit configured to pull-up the first node voltage when the control signal is first level; a pull-down circuit configured to pull-down the first node voltage when the control signal is second level; a monitor configured to cause a second node voltage to be second level when a difference between the input voltage and the first node voltage is larger than a reference voltage; and a second pull-up circuit configured to pull-up the first node voltage when the control signal is first level and also the second node voltage is second level.

### CROSS-REFERENCE TO RELATED APPLICATIONS

This application claims the benefit of Japanese Application No. 2010-209179 filed in Japan on Sep. 17, 2010, the contents of which are incorporated herein by this reference.

### FIELD

Embodiments described herein relate generally to a voltage output circuit.

### BACKGROUND

Heretofore, voltage output circuits to drive an inductive load such as a solenoid in a pulse width modulation (PWM) technique have been known.

A square-wave voltage is applied to a solenoid when the solenoid is driven in the PWM technique. The current of the solenoid is controlled in accordance with the duty cycle of the square wave. Here, if the slew rate of the square wave is high, switching noise occurs due to a back electromotive force generated in the solenoid at the trailing edge of the square wave.

Meanwhile, the occurrence of the noise can be prevented if the change in the gate voltage of an output transistor is set smaller than the slew rate of a PWM input signal to set the slew rate of a square-wave voltage to be applied to the solenoid lower than the slew rate of the input signal.

The setting described above, however, causes an increase in delay of the application of voltage to the solenoid in response to the PWM input signal and thus causes a difference between the duty cycle of the PWM input signal and the duty cycle of the output voltage. As a result, there arises a problem that the control accuracy of the solenoid current is degraded.

### BRIEF DESCRIPTION OF THE DRAWINGS

FIG. 1 is a block diagram for describing a configuration of a voltage output circuit according to an embodiment;

FIG. 2 is a circuit diagram illustrating the voltage output circuit according to the embodiment;

FIG. 3 is a timing chart illustrating an operation of the voltage output circuit according to the embodiment;

FIG. 4 is a timing chart illustrating a primary portion of the operation of the voltage output circuit according to the embodiment;

FIG. 5 is a circuit diagram illustrating a voltage output circuit according to a comparative example; and

FIG. 6 is a timing chart illustrating an operation of the voltage output circuit according to the comparative example.

### DETAILED DESCRIPTION

One embodiment discloses a voltage output circuit comprising: an output transistor of a first conductive type connected between a first terminal to which an input voltage is applied and a second terminal connected to a load, the output transistor having a gate electrode connected to a first node and being switched in accordance with a logical level of a control signal; a first, pull-up circuit including a first resistance connected between the first terminal and the first node, and configured to pull up a voltage of the first node when the control signal is at a first logical level; a pull-down circuit connected between the first node and a reference potential and configured to come into conduction to pull down the voltage of the first node when the control signal is at a second logical level; a gate voltage monitoring circuit connected between the first terminal and the first node and configured to come into conduction to cause a voltage of a second node to be at the second logical level when a difference voltage between the input voltage and the voltage of the first node is larger than a reference voltage; and a second pull-up circuit connected between the first terminal and the first node and configured to come into conduction to pull up the voltage of the first node when the control signal is at the first logical level and also the voltage of the second node is at the second logical level.

Hereinafter, an embodiment of the invention will be described with reference to the drawings. Common reference numerals are used to denote common portions for describing the embodiment throughout the drawings.

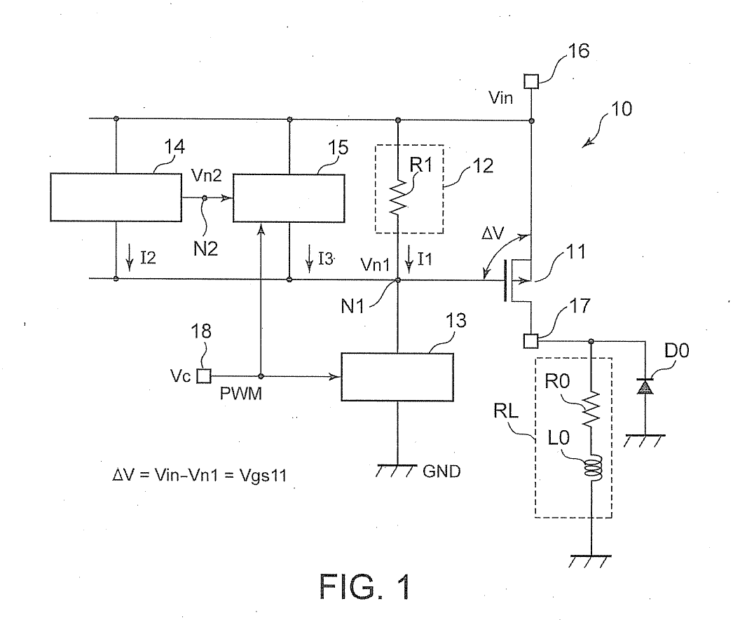

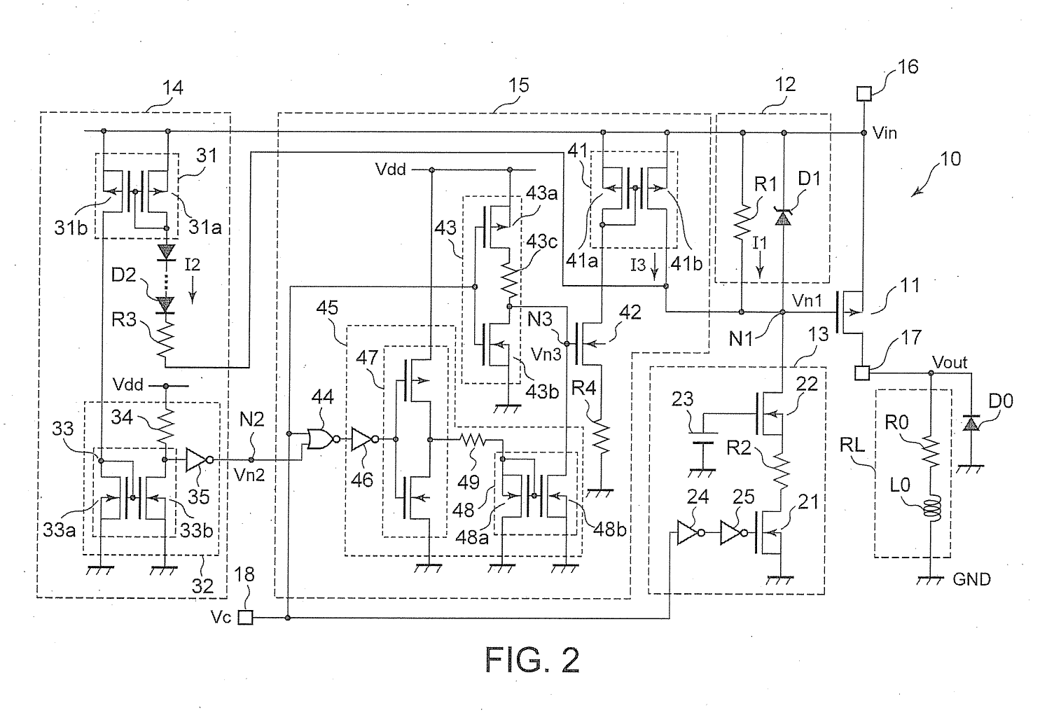

The voltage output circuit according to the embodiment will be described with FIGS. 1 and 2. FIG. 1 is a block diagram for describing a configuration of the voltage output circuit according to the embodiment. FIG. 2 is a circuit diagram illustrating the voltage output circuit. Described in the embodiment is a voltage output circuit to apply a square-wave voltage to an inductive load such as a solenoid to control the current of the solenoid by the duty cycle of the square wave.

As shown in FIG. 1, a voltage output circuit 10 of the embodiment is configured of a P-channel (first conductive type) output transistor 11, a first pull-up circuit 12, a pull-down circuit 13, a gate voltage monitoring circuit 14, and a second pull-up circuit 15.

The output transistor 11 includes a source electrode, a drain electrode, and a gate electrode connected to a first terminal 16, a second terminal 17, and a first node N1, respectively. The output transistor 11 is switched in accordance with a control signal Vc inputted from a third terminal 18.

The output transistor 11 is, for example, a high-breakdown voltage Double Diffusion MOS FET (DMOS transistor). The control signal is a square-wave signal controlled by pulse width modulation (PWM).

An input voltage Vin is applied to the first terminal 16, and an inductive load RL is connected to the second terminal 17. The dielectric load RL is a series circuit of a resistance R0 and a solenoid L0, for example. A diode D0 to discharge a back electromotive force generated in the solenoid L0 when the output transistor 11 is switched off is connected to the second terminal 17.

The first pull-up circuit 12 has a first resistance R1 connected between the first terminal 16 and the first node N1, and pulls up a voltage Vn1 of the first node N1 (hereinafter, referred to as a first node voltage Vn1) when the control signal Vc is at a Low level (first logical level).

The pull-down circuit 13 is connected between the first node N1 and a reference potential GND. The pull-down circuit 13 comes into conduction when the control signal Vc is at a High level (second logical level) to pull down the first node voltage Vn1 so that a predetermined gate voltage causing the output transistor to be switched on can be obtained from the input voltage Vin.

The gate voltage monitoring circuit 14 is connected between the first terminal 16 and the first node N1. The gate voltage monitoring circuit 14 comes into conduction when a difference voltage between the input voltage Vin and the first node voltage Vn1 (ΔV=Vin−Vn1), i.e., a voltage between the gate and source of the output transistor 11 is larger than a reference voltage Vref so as to cause a voltage Vn2 of a second node N2 (hereinafter, referred to as a second node voltage Vn2) to be at the High level.

The second pull-up circuit 15 is connected between the first terminal 16 and the first node N1, and pulls up the first node voltage Vn1 when the, control signal Vc is at the Low level and the second node voltage Vn2 is at the High level.

Next, a description will be given of a configuration of each of the first pull-up circuit 12, the pull-down circuit 13, the gate voltage monitoring circuit 14, and the second pull-up circuit 15.

As shown in FIG. 2, a constant voltage diode D1 is connected in parallel to the first resistance R1 in the first pull-up circuit 12. The first resistance R1 causes a current I1 to flow through the first node N1. The constant voltage diode D1 is used to clamp the first node voltage Vn1 with a zener voltage Vz and thus to prevent the gate voltage of the output transistor 11 from becoming excessively large. The voltage between the gate and source of the output transistor 11 is limited to a value not greater than the zener voltage Vz.

The pull-down circuit 13 includes a series circuit of a second resistance R2 and an N-channel (second conductive type) first transistor 21 (hereinafter, referred to as an NMOS transistor 21) being switched in accordance with the control signal Vc.

Furthermore, an NMOS transistor 22 is connected between the first node N1 and the second resistance R2. A gate electrode of the NMOS transistor 22 is connected to a bias power supply 23. The NMOS transistor 22 is always in an ON-state. The NMOS transistor 22 is provided to adjust a current flowing through the second resistance R2 and thus to determine an operating point of the output transistor 11.

The control signal Vc is inputted to the gate electrode of the NMOS transistor 21 via inverters 24, 25. The inverters 24, 25 are provided to adjust a timing at which the NMOS transistor 21 is switched.

A P-channel first current mirror circuit 31 is connected to the first terminal 16 in the gate voltage monitoring circuit 14. A series circuit of N-stage diodes D2 and a third resistance R3 is connected between a current input PMOS transistor 31a of the first current mirror circuit 31 and the first node N1.

The first current mirror circuit 31 comes into conduction when the difference voltage ΔV is larger than the reference voltage Vref so as to cause a current 12 to flow through the first node N1. The current 12 is used to monitor the gate voltage of the output transistor 11.

Here, the reference voltage Vref is a voltage equal to a sum of the voltage between the drain and source of the PMOS transistor 31a, the forward voltage of the N-stage diodes D2, and the voltage drop of the third resistance R3 caused by the current I2.

A current-voltage conversion circuit 32 is connected to a current output PMOS transistor 31b of the first current mirror circuit 31. The current-voltage conversion circuit 32 copies the current 12 and causes the second node N2 to be at the High level when the current 12 flows through the first current mirror circuit 31.

The current-voltage conversion circuit 32 includes a current mirror circuit 33 having a current input NMOS transistor 33a connected to the PMOS transistor 31b, and a current output NMOS transistor 33b connected to a power supply (not shown) of a voltage Vdd through a resistance 34. In addition, the current-voltage conversion circuit 32 includes an inverter 35 connected between a connection node of the NMOS transistor 33b and the resistance 34, and the second node N2.

A P-channel second current mirror circuit 41 is connected to the first terminal 16 in the second pull-up circuit 15. A series circuit of an NMOS transistor 42 and a fourth resistance R4 is connected between a current input PMOS transistor 41a of the second current mirror circuit 41 and a reference potential GND.

The NMOS transistor 42 is switched in accordance with the logical level of the second node N2 and the logical level of the control signal Vc. When the NMOS transistor 42 is switched ON, the second current mirror circuit 41 causes a current 13 to flow through the first node N1.

An inverter 43 is connected between the third terminal 18 and a third node N3. In the inverter 43, a resistance 43c is connected between a PMOS transistor 43a and an NMOS transistor 43b. The inverter 43 causes a voltage Vn3 of the third node N3 (hereinafter, referred to as a third node voltage Vn3) to be at the High level when the control signal Vc is at the Low level. The resistance 43c is provided to restrict the current flowing through the third node N3.

A NOR circuit 44 has two input terminals connected to the second node N2 and the third terminal 18, respectively, and has an output terminal connected to a voltage-current conversion circuit 45. The voltage-current conversion circuit 45 includes a series circuit of an inverter 46 and an inverter 47, and also includes an N-channel current mirror circuit 48.

In the current mirror circuit 48, a current input NMOS transistor 48a is connected to the output terminal of the inverter 47 through a resistance 49. In addition, a current output NMOS transistor 48b is connected to the third node N3. The resistance 49 is provided to set an input current of the current mirror circuit 48.

The NOR circuit 44 causes its output to be at the High level when the control signal Vc is at the Low level and also the second node voltage Vn2 is at the Low level. The voltage-current conversion circuit 45 switches ON the NMOS transistor 48b when the output of the NOR circuit 44 is at the High level. In this event, since the third node voltage Vn3 is at the High level, a drain current flows through the NMOS transistor 48b, and pulls down the third node voltage Vn3.

The aforementioned voltage output circuit 10 is configured to pull up the first node voltage Vn1 by the currents I1, I2, I3 at a first slew rate when the difference voltage ΔV=Vin−Vn1 is larger than the reference voltage Vref at the trailing edge of the control signal Vc and to pull up the first node voltage Vn1 by only the current I1 at a second slew rate lower than the first slew rate when the difference voltage ΔV becomes smaller than the reference voltage Vref at the trailing edge of the control signal Vc.

Thus, the gate voltage of the output transistor 11 decreases rapidly at the beginning and then starts to decrease moderately once reaching the reference voltage Vref. This makes it possible to suppress the occurrence of the switching noise while suppressing the difference between the duty cycle of the control signal Vc and the duty cycle of the output voltage Vout.

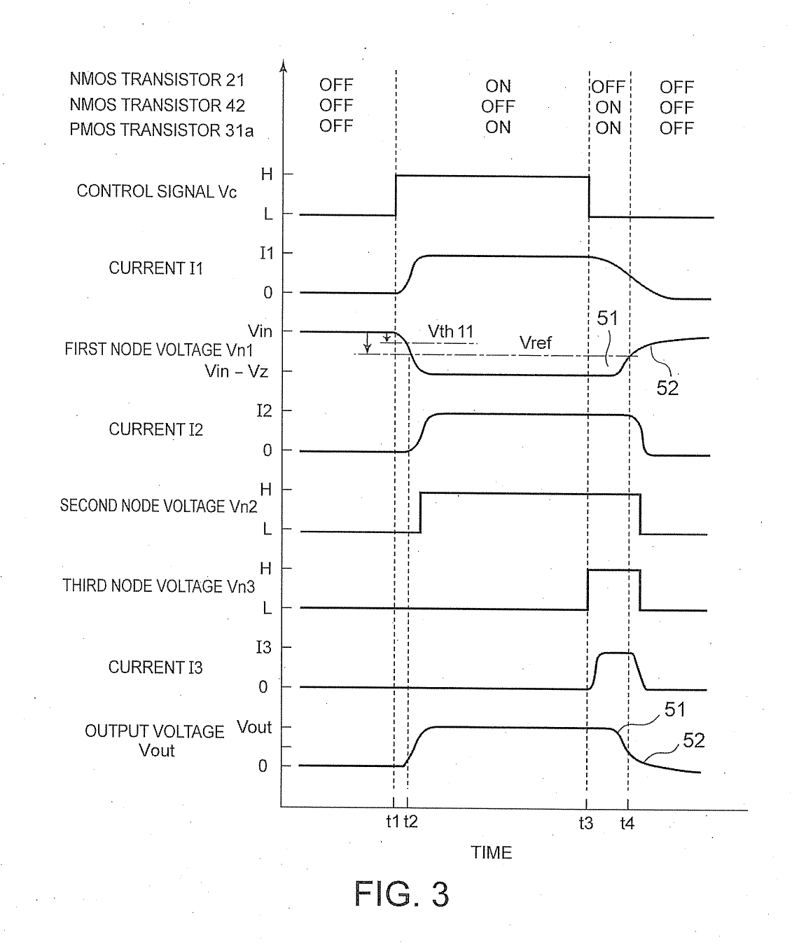

Next, an operation of the voltage output circuit 10 will be described. FIG. 3 is a timing chart illustrating an operation of the voltage output circuit 10. As shown in FIG. 3, as the initial state, when the control signal Vc is at the Low level, the pull-down circuit 13 is not in conduction. In addition, the first node voltage Vn1 is equal to the input voltage Vin, the currents I1, I2, I3 are zero, the second and third node voltages Vn2, Vn3 are at the Low level, and the output voltage Vout is zero in this state.

When the control signal Vc becomes at the High level at a time t1, the pull-down circuit 13 comes into conduction after the delay time of the inverters 24, 25, and the current I1 flows into the first resistance R1, and the first node voltage Vn1 is pulled down in response to this flow of the current I1. The change in the first node voltage Vn1 depends on a period of time during which the gate capacitance of the output transistor 11 is charged.

At a time t2, the first node voltage Vn1 is pulled down, and when the difference voltage ΔV=Vin−Vn1 becomes larger than the reference voltage Vref, the current I2 starts flowing. Then, when the voltage drop of the resistance 34 becomes large, the inverter 35 inverts the input signal, and thus, the second node voltage Vn2 becomes at the High level.

At this time, since the third node voltage Vn3 remains at the Low level, the current I3 does not flow and remains zero.

At a time t3, when the control signal Vc falls from the High level to the Low level, the pull-down circuit 13 becomes nonconductive after the delay time of the inverters 24, 25.

Here, since the third node voltage Vn3 becomes at the High level, the NMOS transistor 42 is switched ON, and the current 13 starts flowing.

Thus, the first node voltage Vn1 is pulled up by the currents I1, I2, I3 at a first slew rate 51. The change in the first node voltage Vn1 depends on a period of time during which the gate capacitance of the output transistor is discharged. Accordingly, the output voltage Vout decreases at the first slew rate 51 as in the case of the first node voltage Vn1.

The current I2 is used to monitor the gate voltage of the output transistor 11. Thus, it is not preferable to cause an excessively large current to flow. The current I3 is preferably set to be sufficiently larger than the current I1 due to the reasons described later.

At a time t4, the first node voltage Vn1 is increased, and when the difference voltage ΔV=Vin−Vn1 becomes smaller than the reference voltage Vref, the current I2 stops flowing. Then, when the voltage drop of the resistance 34 becomes small, the inverter 35 inverts the input signal, and thus, the second node voltage Vn2 becomes at the Low level.

When the control signal Vc is at the Low level, and the second node voltage Vn2 becomes at the Low level, the output of the NOR circuit 44 becomes at the High level. Thus, the NMOS transistor 48b of the current mirror circuit 48 becomes the ON state. The third node voltage Vn3 is pulled down from the High level to the Low level, the NMOS transistor 42 is switched OFF, and the current 13 stops flowing.

Accordingly, the first node voltage Vn1 is pulled up by only the current I1 at a second slew rate 52. Here, since the current I3 no longer flows, the second slew rate 52 becomes lower than the first slew rate 51. Accordingly, the output voltage Vout decreases at the second slew rate 52 as in the case of the first node voltage Vn1.

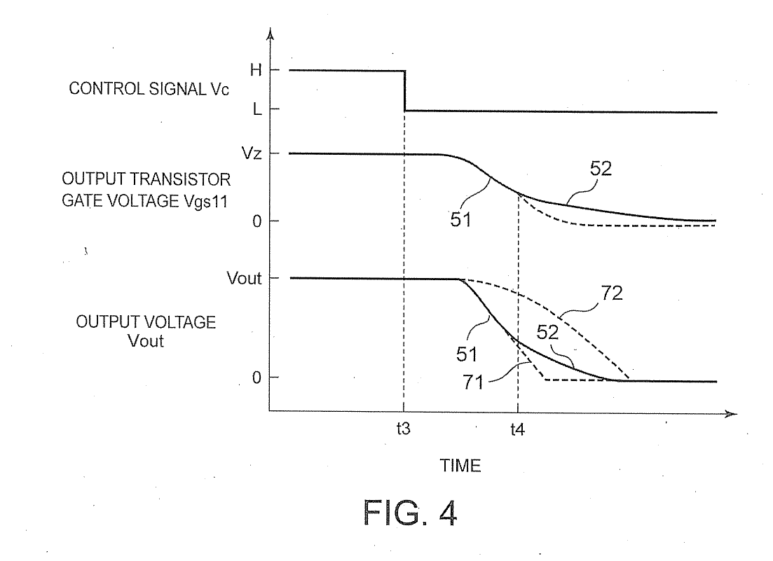

FIG. 4 is a timing chart showing a relationship among the gate voltage of the output transistor 11, the first node voltage Vn1, and the output voltage Vout to be applied to the load RL. As described above, during the period between the time t3 at which the control signal Vc becomes the Low level and the time t4 at which the difference voltage ΔV becomes equal to the reference voltage Vref, the gate voltage of the output transistor 11 decreases at the first slew rate 51 and the output voltage Vout decreases accordingly.

After the time t4, the gate voltage of the output transistor 11 decreases at the second slew rate 52 lower than the first slew rate 51, and the output voltage Vout decreases accordingly.

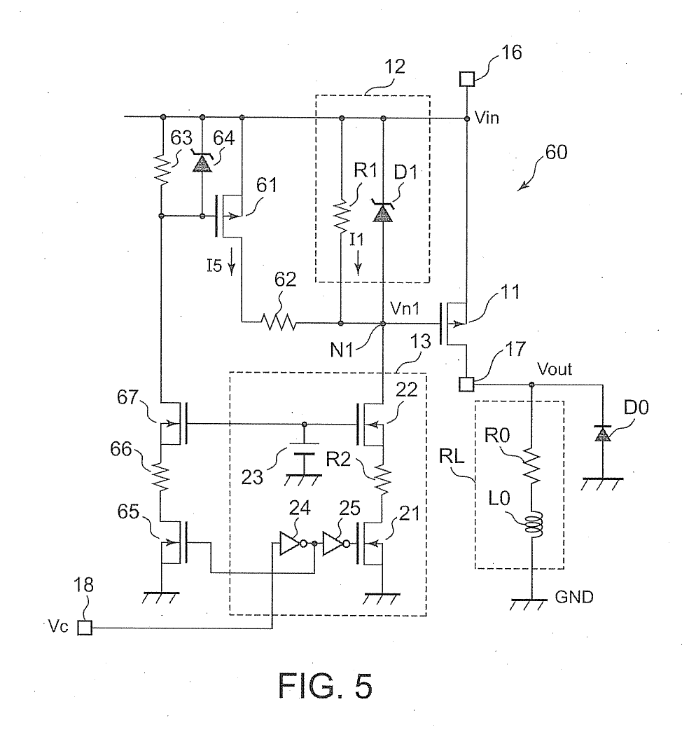

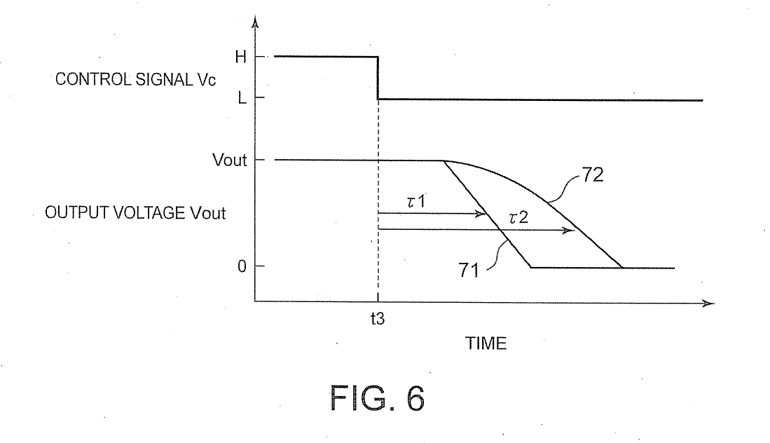

FIG. 5 is a diagram showing a voltage output circuit according to a comparative example, and FIG. 6 is a timing chart showing an operation of the voltage output circuit according to the comparative example. As shown in FIG. 5, in a voltage output circuit 60 according to the comparative example, a PMOS transistor 61 is connected between the first terminal 16 and the first node N1 through a resistance 62.

A parallel circuit of a resistance 63 and a constant voltage diode 64 is connected between the first terminal 16 and the. PMOS transistor 61. The constant voltage diode is provided to clamp the gate voltage of the PMOS transistor 61.

A series circuit of an NMOS transistor 65, a resistance 66, and an NMOS transistor 67 is connected between the gate electrode of the PMOS transistor 61 and a reference potential GND. The MOS transistor 65 has a gate electrode connected to the output terminal of the inverter 24. The NMOS transistor 67 has a gate electrode connected to the bias power supply 23 and is always in an ON state as in the case of the NMOS transistor 22.

When the control signal Vc is at the High level, the NMOS transistor 65 is OFF, and the PMOS transistor 61 is thus OFF as well. Once the control signal Vc becomes at the Low level, the NMOS transistor 65 is switched ON, and the PMOS transistor 61 is thus switched ON as well. Thereby, a drain current 15 flows through the first node N1. The drain current 15 of the PMOS transistor 61 is determined by the resistance 62.

Once the PMOS transistor 61 is switched ON, pull-up is performed by the current Il flowing through the first resistance R1 and the drain current 15 of the PMOS transistor 61.

As shown in FIG. 6, when the resistance 62 is sufficiently small, and the drain current I5 is sufficiently larger than the current I1, the slew rate for the pull-up is substantially determined by the drain current I5. Thus, the slew rate at which the output voltage Vout decreases becomes high as shown by a solid line 71.

When the slew rate is high, a delay τ1 becomes small. Thus, the difference between the duty cycle of the control signal Vc and the duty cycle of the output voltage Vout becomes small. Accordingly, the control accuracy of the solenoid current improves, but noise is likely to occur.

On the other hand, when the resistance 62 is sufficiently large, and the drain current I5 is sufficiently smaller than the current I1, the slew rate for the pull-up is substantially determined by the current I1. Thus, the slew rate at which the output voltage Vout decreases becomes low as shown by a solid line 72.

When the slew rate is low, the occurrence of the noise can be suppressed. However, since a delay τ2 becomes large, the difference between the duty cycle of the control signal Vc and the duty cycle of the output voltage Vout becomes large. Accordingly, the control accuracy of the solenoid current deteriorates.

Accordingly, in the voltage output circuit 60 according to the comparative example, it is impossible to suppress the difference between the duty cycle of the control signal Vc and the duty cycle of the output voltage Vout while suppressing occurrence of the switching noise at the same time.

Meanwhile, in the voltage output circuit 10 according to the embodiment, the gate voltage of the output transistor 11 is fed back to the second pull-up circuit 15, and the gate voltage of the output transistor 11 is compared with the reference voltage Vref as described above.

When the gate voltage of the output transistor 11 is larger than the reference voltage Vref, i.e., when the current flowing through the solenoid L0 is large, the gate voltage is pulled down rapidly at the first slew rate 51. Meanwhile, when the gate voltage of the output transistor 11 is smaller than the reference voltage Vref, i.e., the current flowing through the solenoid L0 is small, the gate voltage is pulled down moderately at the second slew rate 52.

Accordingly, in the voltage output circuit 60 according to the embodiment, it is possible to suppress the difference between the duty cycle of the control signal Vc and the duty cycle of the output voltage Vout while suppressing occurrence of the switching noise at the same time.

As described above, in the voltage output circuit 10 according to the embodiment, if the difference voltage ΔV=Vin−Vn1 is larger than the reference voltage Vref when the control signal Vc falls off, the first node voltage Vn1 is pulled up at the first slew rate, and when the difference voltage ΔV becomes smaller than the reference voltage Vref, the first node voltage Vn1 is pulled up at the second slew rate lower than the first slew rate.

As a result, it is possible to suppress the difference between the duty cycle of the control signal Vc and the duty cycle of the output voltage Vout by use of the first slew rate, which is higher than the second slew rate, while suppressing the occurrence of the switching noise by use of the second slew rate, which is lower than the first slew rate. Accordingly, a voltage output circuit with small switching noise can be obtained.

The aforementioned embodiment is shown as only an exemplary embodiment and is not intended to limit the scope of the invention. Actually, the new circuit described herein may be embodied in various forms, and furthermore, various omissions, replacements and modifications may be made in the form of the circuit described herein, unless such omissions, replacements and modifications depart from the gist or spirit of the invention. Appended claims and equivalents of the appended claims are intended to include the aforementioned forms or changes in such a way that the forms or changes fall within the scope and the gist or spirit of the invention.

In addition, the invention has been described using one embodiment herein, but the invention is not limited to this embodiment.

What is claimed is:

1. A voltage output circuit comprising:
an output transistor of a first conductive type connected between a first terminal to which an input voltage is applied and a second terminal connected to a load, the output transistor having a gate electrode connected to a first node and being switched in accordance with a logical level of a control signal;
a first pull-up circuit including a first resistance connected between the first terminal and the first node, and configured to pull up a voltage of the first node when the control signal is at a first logical level;
a pull-down circuit connected between the first node and a reference potential and configured to come into conduction to pull down the voltage of the first node when the control signal is at a second logical level;
a gate voltage monitoring circuit connected between the first terminal and the first node and configured to come into conduction to cause a voltage of a second node to be at the second logical level when a difference voltage between the input voltage and the voltage of the first node is larger than a reference voltage; and
a second pull-up circuit connected between the first terminal and the first node and configured to come into conduction to pull up the voltage of the first node when the control signal is at the first logical level and also the voltage of the second node is at the second logical level.

2. The voltage output circuit according to claim 1, wherein, when the control signal is at the first logical level and also the voltage of the second node is at the second logical level, the voltage of the first node is pulled up at a first slew rate in accordance with a first current flowing through the first pull-up circuit, a second current flowing through the gate voltage monitoring circuit and a third current flowing through the second pull-up circuit, and
when the control signal is at the first logical level and the voltage of the second node changes to the first logical level from the second logical level, the voltage of the first node is pulled up at a second slew rate in accordance with the first current, the second slew rate being lower than the first slew rate.

3. The voltage output circuit according to claim 1, wherein the pull-down circuit includes a series circuit of a second resistance and a first transistor of a second conductive type being switched in accordance with the control signal.

4. The voltage output circuit according to claim 1, wherein the gate voltage monitoring circuit includes:
a first current mirror circuit of the first conductive type connected to the first terminal;
a series circuit of a plurality of diodes and a third resistance, the series circuit connected between a current input transistor of the first current mirror circuit and the first node; and
a current-voltage conversion circuit connected between a current output transistor of the first current mirror circuit and the reference potential.

5. The voltage output circuit according to claim 1, wherein the second pull-up circuit includes:
a second current mirror circuit of the first conductive type connected to the first terminal;
a series circuit of a fourth resistance and a second transistor of a second conductive type, the second transistor connected between a current input transistor of the second current mirror circuit and the reference potential and being switched in accordance with a voltage of a third node;
an inverter configured to output, to the third node, a signal obtained by inverting the control signal;
a NOR circuit configured to perform a NOR operation of the voltage of the second node and the control signal; and
a voltage-current conversion circuit configured to pull down the voltage of the third node in accordance with an output of the NOR circuit.

6. The voltage output circuit according to claim 4, wherein the current-voltage conversion circuit includes:
a third current mirror circuit of the second conductive type through which an output current of the first current mirror circuit is caused to flow;
a fifth resistance connected between a drain electrode of a current output transistor of the third current mirror circuit and a power supply; and
a second inverter connected between the drain electrode of the current output transistor of the third current mirror circuit and the second node.

7. The voltage output circuit according to claim 5, wherein the voltage-current conversion circuit includes:
a series circuit of a third inverter and a fourth inverter, the series circuit being connected to the NOR circuit; and
a fourth current mirror circuit of the second conductive type having a current input transistor and a current output transistor, the current input transistor connected to the fourth inverter through a sixth resistance, the current output transistor connected between the third node and the reference potential.

8. A voltage output circuit comprising:
a first terminal to which an input voltage is applied;
a second terminal to which an inductive load is connected;
a third terminal to which a control signal is inputted;
a transistor having a source and a drain, the source connected to the first terminal, the drain connected to the second terminal;
a pull-up circuit configured to pull up a potential of a gate of the transistor when the control signal is at a first logical level; and
a pull-down circuit configured to pull down the potential of the gate of the transistor when the control signal is at a second logical level, wherein
the pull-up circuit pulls up the potential of the gate of the transistor at a first slew rate while a potential difference between the gate and source of the transistor is smaller than a predetermined value, and pulls up the potential of the gate of the transistor at a second slew rate lower than the first slew rate while the potential difference between the gate and source of the transistor is larger than the predetermined value.

9. The voltage output circuit according to claim 8, wherein
the pull-up circuit includes:
a first pull-up circuit including a resistance connected between the source and gate of the transistor;
a second pull-up circuit connected between the source and gate of the transistor; and
a gate voltage monitoring circuit connected between the source and gate of the transistor, wherein
the gate voltage monitoring circuit monitors whether or not the potential difference between the gate and source of the transistor is larger than the predetermined value, and
the second pull-up circuit pulls up the potential of the gate of the transistor selectively for a period in which the gate voltage monitoring circuit determines that the potential difference between the gate and source of the transistor is larger than the predetermined value.

10. A voltage output circuit comprising:
a first terminal to which an input voltage is applied;
a second terminal to which an inductive load is connected;
a third terminal to which a control signal is inputted;
a transistor having a source and a drain, the source connected to the first terminal, the drain connected to the second terminal;
a pull-up circuit configured to pull up a potential of a gate of the transistor when the control signal is at a first logical level; and
a pull-down circuit configured to pull down the potential of the gate of the transistor when the control signal is at a second logical level, wherein
the pull-up circuit includes first and second pull-up circuits connected in parallel with each other, and
only the first pull-up circuit operates while a potential difference between the gate and source of the transistor is smaller than a predetermined value, whereas both of the first and second pull-up circuits operate while the potential difference between the gate and source of the transistor is larger than the predetermined value.

11. The voltage output circuit according to claim 10, wherein the first pull-up circuit includes a resistance connected between the source and gate of the transistor.

12. The voltage output circuit according to claim 11, further comprising a gate voltage monitoring circuit connected between the source and gate of the transistor and configured to monitor whether or not the potential difference between the gate and source of the transistor is larger than the predetermined value, wherein
the second pull-up circuit pulls up the potential of the gate of the transistor selectively for a period in which the gate voltage monitoring circuit determines that the potential difference, between the source and gate of the transistor is larger than the predetermined value.
